(19) United States
(12) Patent Application Publication
(10) Pub. No.: US 2022/0271254 A1
(43) Pub. Date: Aug. 25, 2022

(54) Organic Light-Emitting Diode Display with Single Anti-Node Optical Cavities

(71) Applicant: Apple Inc., Cupertino, CA (US)

(72) Inventors: Niva A. Ran, Palo Alto, CA (US); Michelle C. Sherrott, Santa Clara, CA (US); Steven J. Brewer, Atlanta, GA (US); Ping Kuen Daniel Tsang, Taoyuan (TW); KiBeom Kim, Cupertino, CA (US); Hui Lu, Cupertino, CA (US); Siddharth Harikrishna Mohan, Aurora, IL (US)

(21) Appl. No.: 17/569,384

(22) Filed: Jan. 5, 2022

Related U.S. Application Data
(60) Provisional application No. 63/153,837, filed on Feb. 25, 2021.

(51) Int. Cl. H01L 51/52

(52) U.S. Cl. CPC H01L 51/5218; H01L 51/5265; H01L 2251/5392; H01L 2251/558; H01L 51/5004

(57) ABSTRACT

An electronic device may have a display such as an organic light-emitting diode (OLED) display. The OLED display may have an array of OLED pixels that each have OLED layers interposed between a cathode and an anode. The pixels may be microcavity OLED pixels having optical cavities. The optical cavities may be defined by a partially transparent cathode layer and a reflective anode structure. The distance between the partially transparent cathode layer and the reflective anode structure for a pixel may be selected such that light at the wavelength emitted by the pixel forms a standing wave between the anode and the cathode. The standing wave may have only one anti-node and the emissive layer for the pixel may be aligned with that one anti-node. To mitigate short circuits, a roughness reduction layer and/or short-circuit-reducing layer having a high sheet resistance may be formed between the anode the OLED layers.

This application claims the benefit of provisional patent application No. 63/153,837, filed Feb. 25, 2021, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels. In this type of display, each pixel includes a light-emitting diode and thin-film transistors for controlling application of a signal to the light-emitting diode to produce light. The light-emitting diodes may include OLED layers positioned between an anode and a cathode. To emit light from a given pixel in an organic light-emitting diode display, a voltage may be applied to the anode of the given pixel.

It is within this context that the embodiments herein arise.

### SUMMARY

An electronic device may have a display such as an organic light-emitting diode display. The organic light-emitting diode (OLED) display may have an array of organic light-emitting diode pixels that each have OLED layers interposed between a cathode and an anode.

The pixels in the OLED display may be microcavity OLED pixels having optical cavities. The optical cavities may be defined by a partially transparent cathode layer and a reflective anode structure. The distance between the partially transparent cathode layer and the reflective anode structure for a pixel may be selected such that light at the wavelength emitted by the pixel forms a standing wave between the anode and the cathode. The standing wave may have only one anti-node and the emissive layer for the pixel may be aligned with that one anti-node.

Using single anti-node microcavity organic light-emitting diode pixels in the display may reduce the thickness of the display relative to using dual anti-node microcavity organic light-emitting diode pixels. The reduced thickness may make the display pixels susceptible to short circuits between the anode and the cathode. To mitigate short circuits, processing and deposition techniques may be used to reduce inherent roughness in the anode material surface. To mitigate short circuits, a roughness reduction layer may cover the anode to mitigate surface roughness in the anode. To mitigate short circuits, a short-circuit-reducing layer having a high sheet resistance may be formed between the anode the OLED layers for the pixel.

The electron mobility of the electron transport layer in the OLED pixel may be the same or similar to the hole mobility of the hole transport layer in the OLED pixel. An electron blocking layer and a hole blocking layer may be included in the OLED layers. The highest occupied molecular orbital (HOMO) and lowest unoccupied molecular orbital (LUMO) of each OLED layer may be selected to ensure proper transport of electrons and holes within the OLED layers.

### BRIEF DESCRIPTION OF THE DRAWINGS

FIG. 1 is a schematic diagram of an illustrative electronic device having a display in accordance with an embodiment.

FIG. 2 is a schematic diagram of an illustrative display in accordance with an embodiment.

FIG. 3 is a diagram of an illustrative display pixel circuit in accordance with an embodiment.

FIG. 4 is a cross-sectional side view of an illustrative display with organic light-emitting diode layers in accordance with an embodiment.

FIG. 5 is a cross-sectional side view of an illustrative display having dual anti-node microcavity organic light-emitting diode pixels in accordance with an embodiment.

FIG. 6 is a cross-sectional side view of an illustrative display having single anti-node microcavity organic light-emitting diode pixels in accordance with an embodiment.

FIG. 7 is a graph of normalized luminance as a function of viewing angle for both a display with dual anti-node microcavity organic light-emitting diode pixels and a display with single anti-node microcavity organic light-emitting diode pixels in accordance with an embodiment.

FIG. 8 is a graph of white color change as a function of viewing angle for both a display with dual anti-node microcavity organic light-emitting diode pixels and a display with single anti-node microcavity organic light-emitting diode pixels in accordance with an embodiment.

FIG. 9A is a graph of normalized intensity as a function of wavelength for a dual anti-node microcavity organic light-emitting diode pixel in accordance with an embodiment.

FIG. 9B is a graph of normalized intensity as a function of wavelength for a single anti-node microcavity organic light-emitting diode pixel in accordance with an embodiment.

FIG. 10 is a graph of normalized intensity as a function of wavelength (spectral output) for an emissive layer of an organic light-emitting diode pixel in accordance with an embodiment.

FIG. 11A is a cross-sectional side view of an illustrative display with organic light-emitting diode layers that include a hole blocking layer and an electron blocking layer in accordance with an embodiment.

FIG. 11B is a band diagram showing the relative energy levels of the components of the OLED display of FIG. 11A in accordance with an embodiment.

FIG. 12 is a cross-sectional side view of an illustrative display having an anode with surface roughness that causes a short circuit in accordance with an embodiment.

FIG. 13 is a cross-sectional side view of an illustrative display having an anode that is covered by a roughness reduction layer in accordance with an embodiment.

FIG. 14 is a circuit diagram showing how a short reduction layer may be included in an OLED display to mitigate short circuits in accordance with an embodiment.

FIG. 15 is a cross-sectional side view of an illustrative display having an anode and a short reduction layer that is interposed between the anode and a pixel definition layer in accordance with an embodiment.

FIG. 16 is a cross-sectional side view of an illustrative display having an anode and a short reduction layer that is formed over a pixel definition layer in accordance with an embodiment.

FIG. 17 is a cross-sectional side view of an illustrative display having an anode and a short reduction layer that forms an upper layer in the anode in accordance with an embodiment.

### DETAILED DESCRIPTION

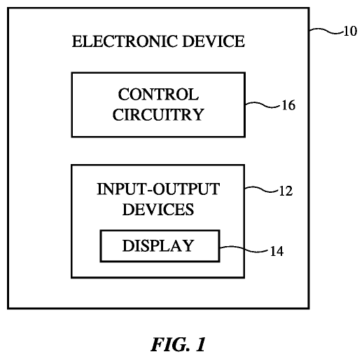

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

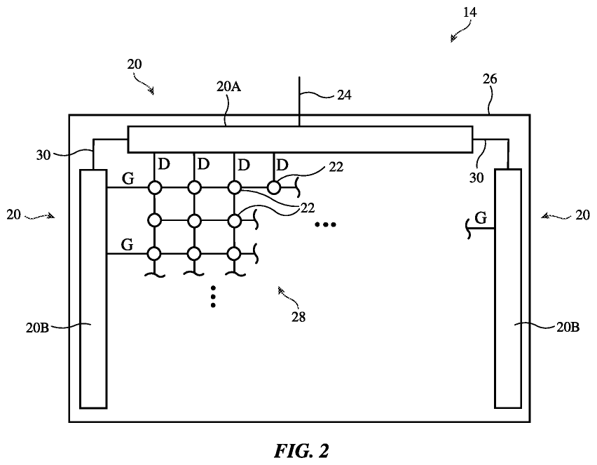

FIG. 2 is a diagram of an illustrative display 14. As shown in FIG. 2, display 14 may include layers such as substrate layer 26. One or more layers in the display (such as substrate layer 26, a cover glass for the display, etc.) may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels. Pixels of other colors such as cyan, magenta, and yellow might also be used.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally across display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

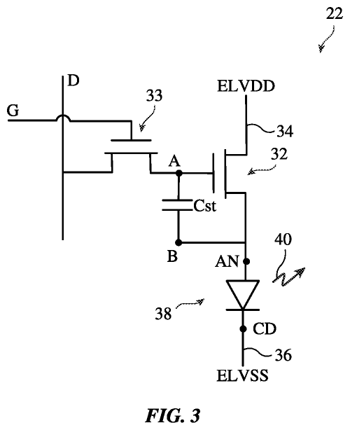

A schematic diagram of an illustrative pixel circuit of the type that may be used for each pixel 22 in array 28 is shown in FIG. 3. As shown in FIG. 3, display pixel 22 may include light-emitting diode 38. A positive power supply voltage ELVDD may be supplied to positive power supply terminal 34 and a ground power supply voltage ELVSS may be supplied to ground power supply terminal 36. Diode 38 has an anode (terminal AN) and a cathode (terminal CD). The state of drive transistor 32 controls the amount of current flowing through diode 38 and therefore the amount of emitted light 40 from display pixel 22. Cathode CD of diode 38 is coupled to ground terminal 36, so cathode terminal CD of diode 38 may sometimes be referred to as the ground terminal for diode 38.

To ensure that transistor 38 is held in a desired state between successive frames of data, display pixel 22 may include a storage capacitor such as storage capacitor Cst. The voltage on storage capacitor Cst is applied to the gate of transistor 32 at node A to control transistor 32. Data can be loaded into storage capacitor Cst using one or more switching transistors such as switching transistor 33. When switching transistor 33 is off, data line D is isolated from storage capacitor Cst and the gate voltage on terminal A is equal to the data value stored in storage capacitor Cst (i.e., the data value from the previous frame of display data being displayed on display 14). When gate line G (sometimes referred to as a scan line) in the row associated with display pixel 22 is asserted, switching transistor 33 will be turned on and a new data signal on data line D will be loaded into storage capacitor Cst. The new signal on capacitor Cst is applied to the gate of transistor 32 at node A, thereby adjusting the state of transistor 32 and adjusting the corresponding amount of light 40 that is emitted by light-emitting diode 38.

If desired, the circuitry for controlling the operation of light-emitting diodes for display pixels in display 14 (e.g., transistors, capacitors, etc. in display pixel circuits such as the display pixel circuit of FIG. 3) may be formed using other configurations (e.g., configurations that include circuitry for compensating for threshold voltage variations in drive transistor 32, etc.). The display pixel may include additional switching transistors, emission transistors in series with the drive transistor, etc. Capacitor Cst may be positioned at other desired locations within the pixel (e.g., between the source and gate of the drive transistor). The display pixel circuit of FIG. 3 is merely illustrative.

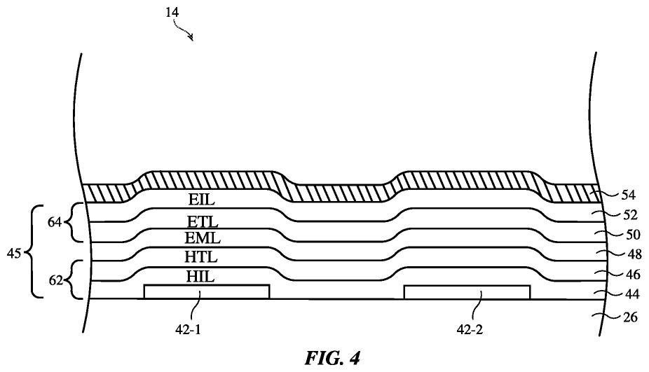

FIG. 4 is a cross-sectional side view of an illustrative display with organic light-emitting diode display pixels. As shown, display 14 may include a substrate 26. Substrate 26 may be formed from glass, plastic, polymer, silicon, or any other desired material. Anodes such as anodes 42-1 and 42-2 may be formed on the substrate. Anodes 42-1 and 42-2 may be formed from conductive material and may be covered by OLED layers 45 and cathode 54. Cathode 54 may be a conductive layer formed on the OLED layers 45. Cathode layer 54 may form a common cathode terminal (see, e.g., cathode terminal CD of FIG. 3) for all diodes in display 14. Cathode layer 54 may be formed from a conductive material that is sufficiently thin to be transparent or partially transparent. Each anode in display 14 may be independently controlled, so that each diode in display 14 can be independently controlled. This allows each pixel to produce an independently controlled amount of light.

The example of cathode layer 54 being transparent (e.g., a transparency of higher than 90%, higher than 95%, higher than 99%, etc.) is merely illustrative. In other arrangements, the display may include an opaque (reflective) cathode and a semi-transparent anode (e.g., having a transparency of less than 90%, less than 80%, less than 70%, or any other desired transparency). In yet another possible arrangement, both the cathode and the anode may be semi-transparent. The display may be, for example, a top-emitting OLED display.

Anodes 42-1 and 42-2 may each be associated with a respective pixel. Although not shown in FIG. 4, display 14 may optionally include a pixel definition layer (PDL). The pixel definition layer may be formed from a dielectric material and may be interposed between adjacent anodes of the display. The pixel definition layer may have openings in which the anodes are formed, thereby defining the light-emitting area (aperture) of each pixel.

As shown, OLED layers 45 (sometimes referred to as an organic stack-up, an organic stack, or an organic light-emitting diode stack) may include a hole injection layer (HIL) 44, a hole transport layer (HTL) 46, an emissive layer (EML) 48, an electron transport layer (ETL) 50, and an electronic injection layer (EIL) 52 interposed between anodes 42 and cathode 54. The hole injection layer and hole transport layer may collectively be referred to as a hole layer (i.e., hole layer 62). The electron transport layer and the electron injection layer may collectively be referred to as an electron layer (i.e., electron layer 64). Emissive layer 48 may include organic electroluminescent material. As shown, hole layer 62 and electron layer 64 may be blanket (common) layers that cover the entire array. In one example, hole injection layer 44 and hole transport layer 46 may be formed from the same base material, with hole injection layer 44 including an additional dopant. Similarly, electron injection layer 52 and electron transport layer 50 may be formed from the same base material, with electron injection layer 52 including an additional dopant. These examples are merely illustrative. Each OLED layer may be formed from any desired material.

The examples of OLED layers included between the anodes 42 and the cathode 54 in FIG. 4 are merely illustrative. If desired, additional layers may be included between anodes 42 and cathode 54 (i.e., an electron blocking layer, a charge generation layer, a hole blocking layer, etc.). The additional layers may be blanket layers (that are uniformly applied to pixels of different colors) or patterned layers (that are patterned for each individual pixel color).

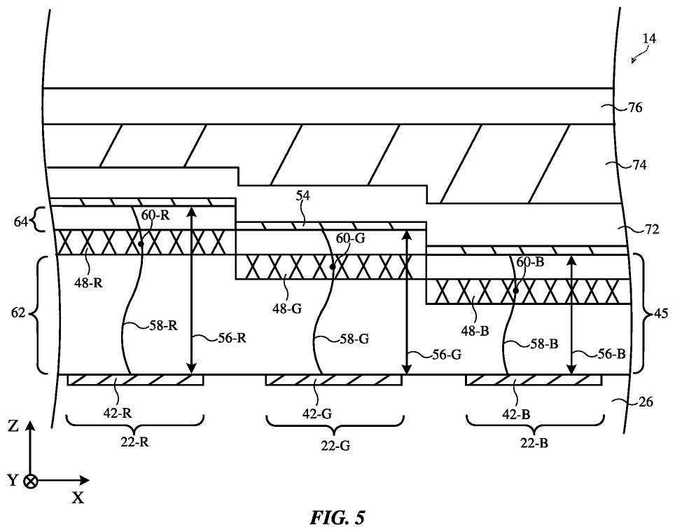

FIG. 5 is a cross-sectional side view of an illustrative display with organic light-emitting diode display pixels. As shown, display 14 may include substrate 26. Substrate 26 may be formed from glass, plastic, polymer, silicon, or any other desired material. Substrate 26 may include thin-film transistor circuitry for applying control signals to the pixels (e.g., to anodes 42) and may therefore sometimes be referred to as a thin-film transistor substrate. FIG. 5 shows a red pixel 22-R, a blue pixel 22-B, and a green pixel 22-G.

Anodes 42 such as anodes 42-R, 42-G, and 42-B may be formed on substrate 26. Anodes 42-R, 42-G, and 42-B may be formed from conductive material and may be covered by OLED layers 45 and cathode 54. OLED layers 45 may include one or more layers for forming an organic light-emitting diode, as shown and discussed in connection with FIG. 4. FIG. 5 shows an example where emissive layer 48 is interposed between hole layer 62 and electron layer 64. Red pixel 22-R has a red emissive layer 48-R, green pixel 22-G has a green emissive layer 48-G, and blue pixel 22-B has a blue emissive layer 48-B. Cathode 54 may be a conductive layer formed on the OLED layers 45. Cathode layer 54 may form a common cathode terminal (see, e.g., cathode terminal CD of FIG. 3) for all diodes in display 14. Each anode in display 14 may be independently controlled, so that each diode in display 14 can be independently controlled. This allows each pixel 22 to produce an independently controlled amount of light.

In some OLED displays, cathode 54 is entirely (or almost entirely) transparent. The display of FIG. 5, however, uses an optical cavity to enhance efficiency and color purity in the display. An optical cavity may be formed by reflective layers within the display that are formed on either side of the OLED layers. By tuning the thickness of the optical cavity that includes the OLED layers, each pixel may be optimized to have high emission at a desired wavelength. To form an optical cavity of this type, display 14 in FIG. 5 includes a partially transparent cathode layer 54 and reflective anodes 42.

Cathode layer 54 may be formed from a partially transparent conductive material. In one illustrative example, cathode layer 54 may be formed from a combination of magnesium (Mg) and silver (Ag). Cathode layer 54 may be formed form any other desired conductive material or combination of conductive materials. Cathode 54 may transmit less than 90% of light, may transmit less than 80% of light, may transmit less than 70% of light, may transmit less than 60% of light, may transmit less than 50% of light, may transmit more than 40% of light, may transmit more than 50% of light, may transmit more than 60% of light, may transmit between 40% and 80% of light, may transmit between 45% and 60% of light, may transmit between 60% and 70% of light, may transmit between 50% and 75% of light, etc. Cathode 54 may reflect more than 10% of light, may reflect more than 20% of light, may reflect more than 30% of light, may reflect more than 40% of light, may reflect more than 50% of light, may reflect more than 60% of light, may reflect less than 50% of light, may reflect less than 60% of light, may reflect between 20% and 60% of light, may reflect between 40% and 55% of light, may reflect between 30% and 40% of light, may reflect between 25% and 50% of light, etc.

Cathode layer 54 may define a first boundary for the optical cavity. The other boundary of the optical cavity may be set by anode 42. Anodes 42-R, 42-G, and 42-B may be formed from a highly reflective material such as aluminum, silver, or any other desired conductive material. The anodes may include one or more conductive layers. Each anode 42 may reflect more than 70% of light, more than 80% of light, more than 90% of light, more than 95% of light, more than 99% of light, etc.

FIG. 5 shows how pixel 22-R has an optical cavity with thickness 56-R between anode 42-R and cathode 54. Pixel 22-G has an optical cavity with thickness 56-G between anode 42-G and cathode 54. Pixel 22-B has an optical cavity with thickness 56-B between anode 42-B and cathode 54.

Each optical cavity thickness is tuned to optimize emission of the desired color of light for that pixel. For a given optical cavity thickness, light of a given wavelength will resonate due to multiple reflections off of the walls (e.g., cathode 54 and anode 42) of the optical cavity and form a standing wave. Standing wave 58-R may be formed by resonance of red light in red pixel 22-R. Standing wave 58-G may be formed by resonance of green light in green pixel 22-G. Standing wave 58-B may be formed by resonance of blue light in blue pixel 22-B. The increased emission at the given wavelength caused by resonance within the optical cavity may be referred to as a microcavity effect. Pixels that are optimized to induce this effect (such as the pixels in FIG. 5) may be referred to as microcavity OLED pixels.

Pixel 22-R has an optical cavity thickness 56-R that maximizes emission of red light. Red light therefore forms a standing wave 58-R in the optical cavity for the red pixel. Pixel 22-G has an optical cavity thickness 56-G that maximizes emission of green light. Green light therefore forms a standing wave 58-G in the optical cavity for the green pixel. Pixel 22-B has an optical cavity thickness 56-B that maximizes emission of blue light. Blue light therefore forms a standing wave 58-B in the optical cavity for the blue pixel. Blue light has a shorter wavelength than green light, which has a shorter wavelength than red light. Generally, the thickness of the optical cavity may be proportional to the wavelength of the type of light that is intended to be emitted. Therefore, thickness 56-B is less than thickness 56-G and thickness 56-G is less than thickness 56-R.

To optimize emission of the desired color of light, the emissive layer for a given pixel may be aligned with one of the anti-nodes of the standing wave for that pixel. Anti-nodes refer to the points on the standing wave having a maximum amplitude. Each standing wave in the OLED display of FIG. 5 has two anti-nodes. Emissive layer 48-R is aligned with anti-node 60-R of standing wave 58-R. Emissive layer 48-G is aligned with anti-node 60-G of standing wave 58-G. Emissive layer 48-B is aligned with anti-node 60-B of standing wave 58-B.

As shown in FIG. 5, additional layers may be formed over cathode 54 in display 14. One or more encapsulation layers 72 is formed over cathode 54. Encapsulation layer 72 may sometimes be referred to as cathode protection layer 72, cathode encapsulation layers 72, or organic encapsulation layers 72. The encapsulation layer 72 may be formed from an organic material, as one example. One or more thin film encapsulation layers 74 may be formed over the cathode encapsulation layers 72. Thin film encapsulation layers 74 may be formed from inorganic layers and/or planarization layers and may sometimes be referred to as inorganic encapsulation layers 74. Thin film encapsulation layer 74 may have a planar upper surface and therefore may be referred to as a planarization layer 74. The planarization layer 74 may planarize height differences caused by the different cavity thicknesses of the pixels.

A transparent cover layer 76 may be formed over the encapsulation layers 74 and 72. Transparent cover layer 76 (sometimes referred to as cover layer 76, display cover layer 76, cover glass 76, display cover glass 76, etc.) may be formed from a transparent material such as glass or plastic. The transparent cover layer 76 may protect the underlying display layers from damage during operation of the display. The example in FIG. 5 is merely illustrative, and additional layers may be included in the display if desired.

The total cavity length of the cavity formed by cathode 54 and a respective anode 42 may be equal to the refractive index of the OLED layers multiplied by the thickness (length) of the cavity (e.g., dimension 56 in FIG. 5). This is represented by the equation L_{CAV}=n×d where L_{CAV} is the total cavity length, n is the refractive index, and d is the thickness of the cavity (e.g., dimension 56). Example cavity thicknesses 56 (d) for FIG. 5 are 270 nanometers for the red pixel, 220 nanometers for the green pixel, and 180 nanometers for the blue pixel. These values are merely illustrative and other thicknesses may be used if desired.

In FIG. 5, the total cavity length L_{CAV} may be equal (or approximately equal) to the wavelength (λ) of light emitted by that pixel. For red pixel 22-R, the total cavity length may be approximately (e.g., within 10%, within 5%, etc.) equal to the wavelength of red light (λ_{RED}). For green pixel 22-G, the total cavity length may be approximately (e.g., within 10%, within 5%, etc.) equal to the wavelength of green light (λ_{GREEN}). For blue pixel 22-R, the total cavity length may be approximately (e.g., within 10%, within 5%, etc.) equal to the wavelength of blue light (λ_{BLUE}).

The refractive index term may be approximately the same for pixels of different colors. Therefore, the ratio of thicknesses 56 for different colored pixels may be the same as the ratio of the wavelengths of light emitted by those pixels. For example, thickness 56-R divided by thickness 56-G may be approximately equal (e.g., within 10% of, within 5% of) to the wavelength of red light divided by the wavelength of green light. Thickness 56-R divided by thickness 56-B may be approximately equal (e.g., within 10% of, within 5% of) to the wavelength of red light divided by the wavelength of blue light. Thickness 56-G divided by thickness 56-B may be approximately equal (e.g., within 10% of, within 5% of) to the wavelength of green light divided by the wavelength of blue light.

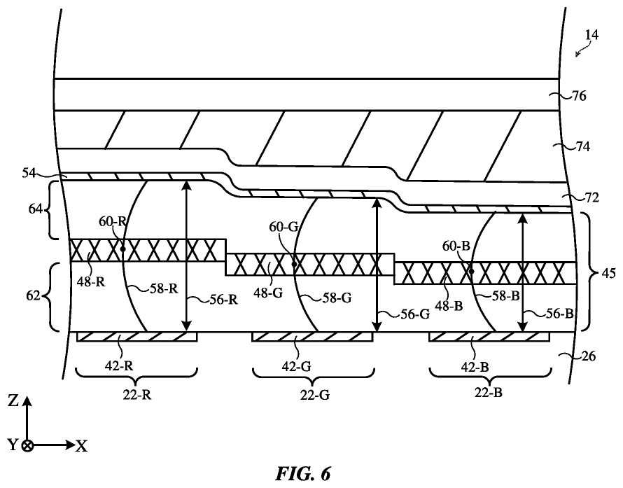

In FIG. 5, the cavity length is equal to the wavelength of light emitted by that pixel and each pixel has a corresponding standing wave with two anti-nodes. This example is merely illustrative. In another possible arrangement, shown in FIG. 6, the total cavity length may be equal to half of the wavelength of light emitted by that pixel (λ/2) and each pixel has a corresponding standing wave with only one anti-node. Display 14 in FIG. 6 may include similar layers as described in connection with FIG. 5. For simplicity, the descriptions of common components will not be repeated.

As shown in FIG. 6, pixel 22-R has an optical cavity thickness 56-R that maximizes emission of red light. Pixel 22-G has an optical cavity thickness 56-G that maximizes emission of green light. Pixel 22-B has an optical cavity thickness 56-B that maximizes emission of blue light. Standing wave 58-R may be formed by resonance of red light in red pixel 22-R. Standing wave 58-G may be formed by resonance of green light in green pixel 22-G. Standing wave 58-B may be formed by resonance of blue light in blue pixel 22-B.

In FIG. 6, the standing waves 58 have only 1 anti-node (instead of 2 anti-nodes as in FIG. 5). To optimize emission of the desired color of light, the emissive layer for a given pixel may be aligned with the anti-node of the standing wave for that pixel. Emissive layer 48-R is aligned with anti-node 60-R of standing wave 58-R. Emissive layer 48-G is aligned with anti-node 60-G of standing wave 58-G. Emissive layer 48-B is aligned with anti-node 60-B of standing wave 58-B.

In FIG. 6, the total cavity length L_{CAV} may be equal (or approximately equal) to half of the wavelength of light emitted by that pixel (λ/2). For red pixel 22-R, the total cavity length may be approximately (e.g., within 10%, within 5%, etc.) equal to half of the wavelength of red light (λ_{RED}/2). For green pixel 22-G, the total cavity length may be approximately (e.g., within 10%, within 5%, etc.) equal to half of the wavelength of green light (λ_{GREEN}/2). For blue pixel 22-R, the total cavity length may be approximately (e.g., within 10%, within 5%, etc.) equal to half of the wavelength of blue light (λ_{BLUE}/2). Thickness 56-R may be 110 nanometers, between 100 nanometers and 120 nanometers, between 90 and 150 nanometers, greater than 90 nanometers, greater than 105 nanometers, less than 120 nanometers, less than 200 nanometers, less than 150 nanometers, etc. Thickness 56-G may be 90 nanometers, between 80 nanometers and 100 nanometers, between 60 and 110 nanometers, greater than 60 nanometers, greater than 80 nanometers, less than 100 nanometers, less than 110 nanometers, less than 125 nanometers, less than 150 nanometers, etc. Thickness 56-B may be 60 nanometers, between 50 nanometers and 70 nanometers, between 50 and 90 nanometers, greater than 50 nanometers, less than 70 nanometers, less than 85 nanometers, less than 90 nanometers, less than 100 nanometers, etc.

As previously discussed, the refractive index term in the equation L_{CAV}=n×d may be approximately the same for pixels of different colors. Therefore, the ratio of thicknesses 56 for different colored pixels in FIG. 6 may be the same as the ratio of the wavelengths of light emitted by those pixels. For example, thickness 56-R divided by thickness 56-G may be approximately equal (e.g., within 10% of, within 5% of) to the wavelength of red light divided by the wavelength of green light. Thickness 56-R divided by thickness 56-B may be approximately equal (e.g., within 10% of, within 5% of) to the wavelength of red light divided by the wavelength of blue light. Thickness 56-G divided by thickness 56-B may be approximately equal (e.g., within 10% of, within 5% of) to the wavelength of green light divided by the wavelength of blue light.

To tune the thicknesses 56 of the OLED microcavities, the thicknesses of one or more OLED layers may be adjusted between pixels of different colors. In one illustrative example, each OLED layer may have a thickness tailored to the color of that pixel. For example, the hole injection layer for a red pixel has a different thickness than the hole injection layer for a green pixel, the hole transport layer for a red pixel has a different thickness than the hole transport layer for a green pixel, the electron injection layer for a red pixel has a different thickness than the electron injection layer for a green pixel, the electron transport layer for a red pixel has a different thickness than the electron transport layer for a green pixel, the emissive layer for a red pixel has a different thickness than the emissive layer for a green pixel, an electron blocking layer for a red pixel has a different thickness than an electron blocking layer for a green pixel, and/or a hole blocking layer for a red pixel has a different thickness than a hole blocking layer for a green pixel. As another example, one or more of the layers may have the same thickness in pixels of different colors for ease of manufacturing. For example, the electron transport layer for a red pixel may have the same thickness as the electron transport layer for a green pixel. In general, each pixel color may have OLED layers of any desired thicknesses that result in the desired total optical cavity lengths and emissive layer alignment (with the anti-node).

The thicknesses, materials, and refractive indices of other layers within display 14 (e.g., encapsulation layers 72 and 74) may also be selected to optimize the performance of display 14 in FIG. 6.

The top-emitting, single anti-node microcavity OLED display of FIG. 6 may have numerous advantages over the dual anti-node microcavity OLED display of FIG. 5. The off-axis performance may be improved by using the display of FIG. 6 compared to the display of FIG. 5.

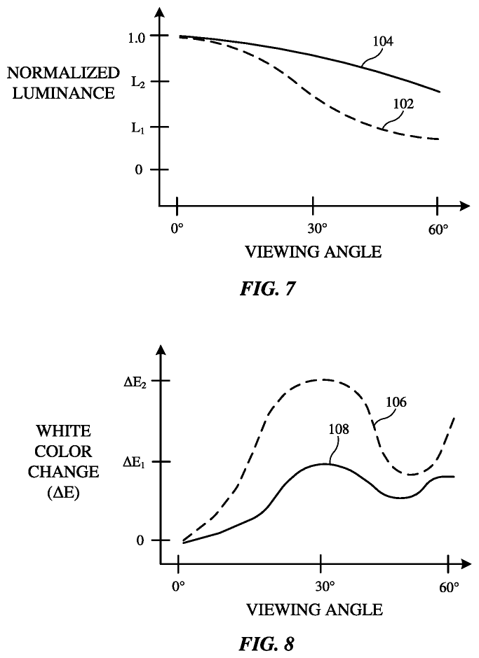

FIG. 7 is a graph of normalized luminance as a function of viewing angle. Profile 102 represents the normalized luminance as a function of viewing angle for the display shown in FIG. 5 (with a standing wave having two anti-nodes). Profile 104 represents the normalized luminance as a function of viewing angle for the display shown in FIG. 6 (with a standing wave having one anti-node). In both displays, the luminance decreases with increasing viewing angle. A viewing angle of 0 degrees refers to viewing the display in a direction parallel to the surface normal of the display (e.g., parallel to the Z-axis in FIGS. 5 and 6). The normalized luminance has a maximum at a viewing angle of 0 degrees (e.g., an on-axis viewing angle). The maximum normalized luminance is 1.0 for both profiles.

As shown, the luminance drop with increasing viewing angle is greater in profile 102 (for FIG. 5) than in profile 104 (for FIG. 6). Profile 102 may drop to a normalized luminance L₁ at 60 degrees. Profile 104 may drop to a normalized luminance L₂ at 60 degrees. L₂ is greater than L₁, which indicates how the off-axis luminance drop is worse in the display of FIG. 5 than in the display of FIG. 6. As an example, L₂ may be greater than 0.8 whereas Li may be less than 0.4. The OLED display of FIG. 6 therefore has improved luminance uniformity relative to the OLED display of FIG. 5.

In addition to improved luminance at off-axis angles, the display of FIG. 6 may have improved color shift at off-axis angles relative to the display of FIG. 5. FIG. 8 is a graph of white color change (ΔE) as a function of viewing angle. Profile 106 represents white color change as a function of viewing angle for the display shown in FIG. 5 (with a standing wave having two anti-nodes). Profile 108 represents the white color change as a function of viewing angle for the display shown in FIG. 6 (with a standing wave having one anti-node). White color change (ΔE) refers to the difference in color perceived by a viewer (e.g., relative to on-axis viewing). The white color change at 0 degrees (on-axis) is therefore 0. At off-axis viewing angles, however, the white color change is greater than 0.

The profile 106 is greater than the profile 108, indicating that the display of FIG. 6 has less color change than the display of FIG. 5. In the display of FIG. 5 (as shown by profile 106), the white color change has a maximum of ΔE₂ at about 30 degrees. In the display of FIG. 6 (as shown by profile 108), the white color change has a maximum of ΔE₁ at about 30 degrees. ΔE₂ is greater than ΔE₁. ΔE₂ may be greater than 7 whereas ΔE₁ may be less than 4. The OLED display of FIG. 6 therefore has improved color shift relative to the OLED display of FIG. 5.

The profiles depicted in FIG. 8 are merely illustrative. In general, the white color change (ΔE) is smaller for displays having a single anti-node cavity (as in FIG. 6) compared to displays having a dual anti-node cavity (as in FIG. 5). The white color change (measured for light inside the transparent layers at the top of the display) for displays of the type shown herein may be less than 15 (or another desired limit) at all viewing angles. Controlling maximum white color change to be within a certain maximum is important for consistent user experience from all viewing angles (on axis to off axis). The maximum permitted white color change may be lower in displays with curvature and/or cover glasses having curvature.

In addition to the white color change described here, primary (red, green, or blue) color shift with viewing angle is also smaller for displays having a single anti-node cavity (as in FIG. 6) compared to displays having a dual anti-node cavity (as in FIG. 5).

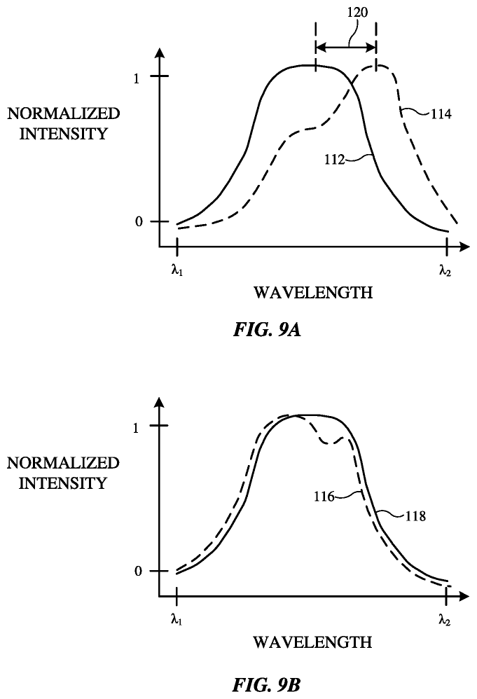

FIGS. 9A and 9B are graphs further showing how the display of FIG. 5 has greater off-axis color shift than the display of FIG. 6. FIG. 9A is a graph of normalized intensity versus wavelength for a green pixel in the display of FIG. 5. Profile 112 is the spectral output of the green pixel at an on-axis (0 degree) viewing angle. Profile 114 is the spectral output of the green pixel at an off-axis (e.g., 80 degree) viewing angle. As shown, the normalized intensity peaks at different wavelengths that are separated by wavelength difference 120. The magnitude of wavelength difference 120 indicates the color shift of the green pixel as a viewer moves from an on-axis viewing angle to an off-axis viewing angle.

FIG. 9B is a graph of normalized intensity versus wavelength for a green pixel in the display of FIG. 6. Profile 118 is the spectral output of the green pixel at an on-axis (0 degree) viewing angle. Profile 116 is the spectral output of the green pixel at an off-axis (e.g., 80 degree) viewing angle. As shown, the normalized intensity peaks at similar wavelengths in both profiles. Therefore, compared to the display of FIG. 5 (as shown in the graph of FIG. 9A), there is a much smaller color shift in the display of FIG. 6 as a viewer moves from an on-axis viewing angle to an off-axis viewing angle.

The profiles depicted in FIGS. 9A and 9B are merely illustrative. In general, the off-axis color shift is smaller for displays having a single anti-node cavity (as in FIG. 6) compared to displays having a dual anti-node cavity (as in FIG. 5).

The display of FIG. 6 may have improved performance relative to the display of FIG. 5 particularly in displays with curvature and/or cover glasses having curvature. Off-axis emission at high angles may be the main cause of color shift as shown in FIGS. 8 and 9A/9B. In a planar display with a planar cover glass, light at high off-axis angles may be trapped in the display due to total internal reflection and therefore not be viewed by a viewer. Color shift is therefore mitigated because the off-axis light does not actually reach the viewer. However, in displays having curved display panels or displays covered by transparent cover layers having curved edges, the off-axis light at high angles may escape the cover glass (e.g., may not be totally internally reflected) and be viewed by the viewer. Mitigating off-axis color shift using the display of FIG. 6 may therefore be particularly useful in these types of applications.

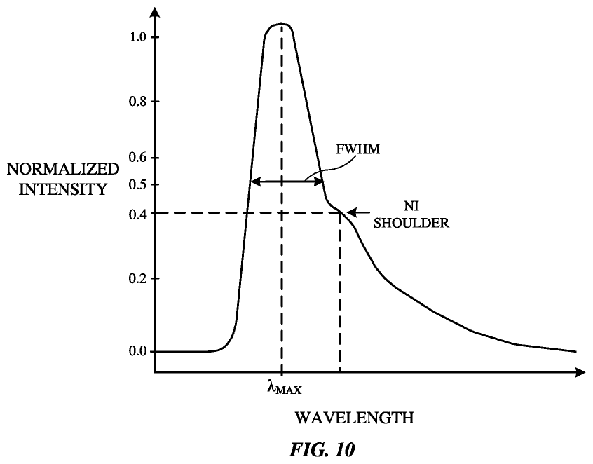

In order to maximize color gamut coverage in a display of the type shown in FIG. 6, the emissive layers of the red, green, and blue pixels may have spectral outputs with specific properties. A representative spectral output (e.g., of an emissive layer in the display) is shown in FIG. 10. The spectral output shows normalized intensity as a function of wavelength for an illustrative emissive layer. There are some key properties of the spectral output that are used to characterize the spectral output. First, the wavelength at which normalized intensity is brightest (e.g., when the normalized intensity is 1.0) may be referred to as λₘₐₓ. The λₘₐₓ describes the dominant color of the spectral output for the emissive layer. The full width of the curve at half of the maximum normalized intensity (sometimes referred to as full width half maximum or full width half max) is another key property of the spectral output. The full width half maximum (FWHM) is labeled in FIG. 10.

Each spectral output may also have a shoulder height. The shoulder height (N_{SHOULDER}) is defined as the normalized intensity at a shoulder point on the profile. The shoulder point on the profile may be the peak of a second gaussian function fit to the profile (in addition to a first gaussian function having a max aligned with λₘₐₓ). The shoulder point may also be an inflection point of the profile (a point at which a change in the direction of curvature occurs).

The emissive layers of the pixels may be formed by dopants in a host material. The dopants and host material may be selected to optimize the spectral output of each color of pixel. The emissive layers may be selected to ensure that the display panel can achieve a full color gamut, for example as defined by the DCI-P3 RGB color space.

There are several options for the spectral output of the blue emissive layer. In one example, λₘₐₓ is 449 nm, the FWHM is 21 nm, and the shoulder height is 0.28. In another example, λₘₐₓ is between 452 and 455 nm, the FWHM is 19 nm, and the shoulder height is 0.28. In another example, λₘₐₓ is between 452 and 455 nm, the FWHM is 21 nm, and the shoulder height is 0.17. As shown by these options, increasing the FWHM may enable the shoulder height to be reduced (e.g., when FWHM increases from 19 nm to 21 nm, the shoulder height drops from 0.28 to 0.17). The λₘₐₓ for the blue emissive layer may therefore be les than 460 nm, less than 455 nm, less than 450 nm, greater than 440 nm, between 445 and 455 nm, etc. The FWHM for the blue emissive layer may be greater than 15 nm, greater than 18 nm, greater than 19 nm, greater than 20 nm, less than 22 nm, less than 21 nm, less than 20 nm, between 18 and 22 nm, etc. The shoulder height for the blue emissive layer may be less than 0.35, less than 0.30, less than 0.25, less than 0.20, greater than 0.15, greater than 0.25, between 0.15 and 0.30, between 0.25 and 0.30, etc. These examples are illustrative only, as there may be additional designs for the spectral output of the blue emissive layer that can satisfy a large color gamut.

There are several options for the spectral output of the green emissive layer. In one example, λₘₐₓ is 522 nm, the FWHM is 27 nm, and the shoulder height is 0.38. In another example, λₘₐₓ is 524 nm, the FWHM is 29 nm, and the shoulder height is 0.30. In another example, λₘₐₓ is 526 nm, the FWHM is 31 nm, and the shoulder height is 0.12. As shown by these options, increasing the FWHM may enable the shoulder height to be reduced (e.g., when FWHM increases from 29 nm to 31 nm, the shoulder height drops from 0.30 to 0.12). The λₘₐₓ for the green emissive layer may therefore be less than 530 nm, less than 525 nm, greater than 520 nm, greater than 525 nm, between 520 and 530 nm, between 521 nm and 527 nm, etc. The FWHM for the green emissive layer may be greater than 20 nm, greater than 25 nm, greater than 27 nm, greater than 29 nm, less than 35 nm, less than 30 nm, less than 29 nm, between 25 and 35 nm, between 26 nm and 32 nm, etc. The shoulder height for the green emissive layer may be less than 0.40, less than 0.35, less than 0.15, greater than 0.10, greater than 0.25, between 0.10 and 0.40, between 0.25 and 0.40, etc. These examples are illustrative only, as there may be additional designs for the spectral output of the green emissive layer that can satisfy a large color gamut.

There are several options for the spectral output of the red emissive layer. In one example, λₘₐₓ is 624 nm, the FWHM is 37 nm, and the shoulder height is 0.20. In another example, λₘₐₓ is 626 nm, the FWHM is 45 nm, and the shoulder height is 0.20. In another example, λₘₐₓ is 628 nm, the FWHM is 50 nm, and the shoulder height is 0.30. The λₘₐₓ for the red emissive layer may therefore be less than 630 nm, less than 628 nm, greater than 620 nm, greater than 624 nm, between 620 and 630 nm, between 623 nm and 629 nm, etc. The FWHM for the red emissive layer may be greater than 20 nm, greater than 30 nm, greater than 40 nm, greater than 45 nm, less than 55 nm, less than 50 nm, less than 40 nm, between 35 and 55 nm, between 30 nm and 60 nm, etc. The shoulder height for the red emissive layer may be less than 0.40, less than 0.35, less than 0.25, greater than 0.15, greater than 0.25, between 0.10 and 0.40, etc. These examples are illustrative only, as there may be additional designs for the spectral output of the red emissive layer that can satisfy a large color gamut.

Using emissive layers having spectral outputs with the characteristics outlined above will allow the display to achieve a full color gamut. The emissive layers may use platinum-based phosphorescent dopants to achieve the target spectral outputs. For example, emissive layer 48-R, emissive layer 48-G, and/or emissive layer 48-B may use platinum-based phosphorescent dopants. The emissive layers may be iridium (Ir) based for improved lifetime/efficiency. For example, emissive layer 48-R, emissive layer 48-G, and/or emissive layer 48-B may be iridium-based emissive layers. The emissive layers may also be fluorescent or hyperfluorescent based emissive layers for improved spectral target and large color gamut. These examples are merely illustrative. In general, any desired materials may be used for the emissive layers of each color.

An OLED display having single anti-node optical cavities (as in FIG. 6) may be thinner than an OLED display having dual anti-node optical cavities (as in FIG. 5). To optimize OLED performance in an OLED display having single anti-node optical cavities, the supply of holes and electrons to the emissive layer for a given pixel may be balanced to avoid efficiency losses and molecular degradation due to polaron-exciton or exciton-exciton quenching processes. Additionally, the OLED performance may be optimized by ensuring that the energy levels of the transport layers and emissive layer are well suited for a balanced supply of charge carriers without being too injection-limited, for example. The supply of holes and electrons to the emissive layer may be balanced by selecting materials for the electron transport layer (ETL) and hole transport layer (HTL) that have similar electron/hole mobilities. Additionally, blocking layers may be incorporated into the OLED display pixels.

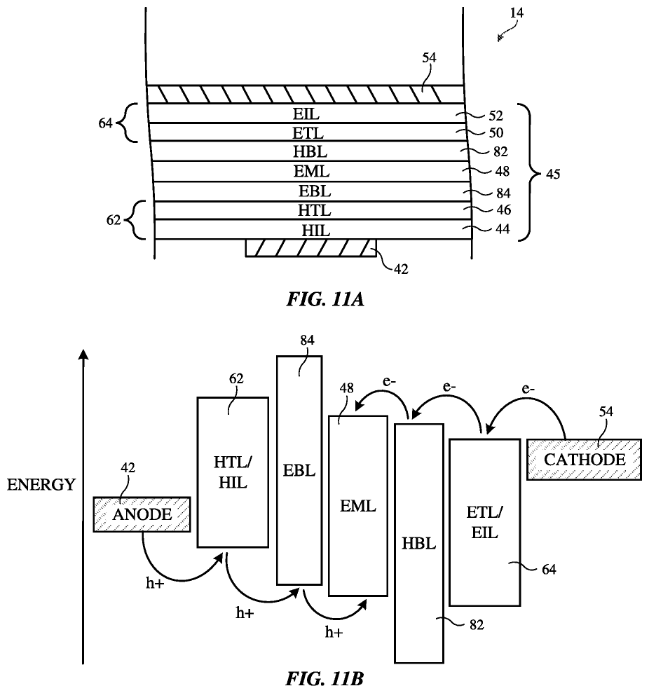

FIG. 11A is a cross-sectional side view of an illustrative OLED display pixel with blocking layers. The OLED display pixel in FIG. 11A may be a single anti-node optical cavity pixel (as shown in FIG. 6). As shown, the display includes an anode 42 and cathode 54. Additional light-emitting diode layers 45 are interposed between the anode and the cathode. Similar to as shown in FIG. 4, a hole injection layer 44 and hole transport layer 46 (sometimes collectively referred to as hole layer 62) are interposed between anode 42 and emissive layer 48. An electron injection layer 52 and electron transport layer 50 (sometimes collectively referred to as electron layer 64) are interposed between cathode 54 and emissive layer 48.

Additionally, display 14 includes a hole blocking layer (HBL) 82 that is interposed between emissive layer 48 and electron transport layer 50 and an electron blocking layer (EBL) 84 that is interposed between emissive layer 48 and hole transport layer 46. Hole blocking layer 82 may block holes from passing from emissive layer 48 into electron transport layer 50. Electron blocking layer 84 may block electrons from passing from emissive layer 48 into hole transport layer 46. Including hole blocking layer 82 and electron blocking layer 84 (sometimes referred to as charge blocking layers) may help ensure a balance of holes and electrons in emissive layer 48.

The magnitude of the mobility (e.g., m²/Vs) for hole transport layer 46 may the same or similar to the magnitude of mobility for electron transport layer 50. The magnitude of the respective mobilities may be, for example, within 1%, within 5%, within 10%, within 30%, within 50%, within 100%, within 1000%, etc. The magnitude of the mobilities may be between (inclusive) 5×10⁻⁹ m²/Vs and 1×10⁻⁸ m²/Vs, as one example.

In other words, the hole mobility for hole transport layer 46 may be between (inclusive) 5×10⁻⁹ m²/Vs and 1×10⁻⁸ m²/Vs and the electron mobility for electron transport layer 50 may be between (inclusive) 5×10⁻⁹ m²/Vs and 1×10⁻⁸ m²/Vs. The electron blocking layer 84 may share the same mobility values as the hole transport layer 46. The hole blocking layer 82 may share the same mobility values as the electron transport layer 50. The electron mobility for electron transport layer 50 may be within 1% of the hole mobility for hole transport layer, within 5% of the hole mobility for hole transport layer, within 10% of the hole mobility for hole transport layer, within 30% of the hole mobility for hole transport layer, within 50% of the hole mobility for hole transport layer, within 100% of the hole mobility for hole transport layer, within 1000% of the hole mobility for hole transport layer, etc. The hole mobility for hole transport layer 46 may be within 1% of the electron mobility for electron transport layer, within 5% of the electron mobility for electron transport layer, within 10% of the electron mobility for electron transport layer, within 30% of the electron mobility for electron transport layer, within 50% of the electron mobility for electron transport layer, within 100% of the electron mobility for electron transport layer, within 1000% of the electron mobility for electron transport layer, etc. The thicknesses of the hole transport layer and the electron transport layer may also be similar (e.g., within 100 nanometers, within 50 nanometers, within 20 nanometers, within 10 nanometers, etc.).

FIG. 11B is a band diagram showing the relative energy levels of the components of the OLED display. Each component in the band diagram has a respective box indicating the highest occupied molecular orbital (HOMO) and lowest unoccupied molecular orbital (LUMO) for that material. In each box, the HOMO is represented by the lower horizontal line and the LUMO is represented by the higher horizontal line. As shown in FIG. 11B, the HOMO for hole layer 62 is higher than the HOMO for electron blocking layer 84. The HOMO for electron blocking layer 84 is in turn higher than the HOMO for emissive layer 48. This allows for holes (h+) to be transported from hole layer 62 to emissive layer 48 as desired.

As shown in FIG. 11B, the LUMO for electron layer 64 is lower than the LUMO for hole blocking layer 82. The LUMO for electron blocking layer 82 is in turn lower than the LUMO for emissive layer 48. This allows for electrons (e−) to be transported from electron layer 64 to emissive layer 48 as desired.

To summarize, the HOMO for hole layer 62 may be higher than or equal to the HOMO for electron blocking layer 84. The HOMO for electron blocking layer 84 may be higher than or equal to the HOMO for emissive layer 48. The LUMO for electron layer 64 may be lower than or equal to the LUMO for hole blocking layer 82. The LUMO for electron blocking layer 82 may be lower than or equal to the LUMO for emissive layer 48.

The LUMO for electron blocking layer 84 may be greater than the LUMO for both hole layer 62 and emissive layer 48. This prevents electrons from passing from emissive layer 48 to hole layer 62. The HOMO for hole blocking layer 82 may be lower than the HOMO for both electron layer 64 and emissive layer 48. This prevents holes from passing from emissive layer 48 to electron layer 64.

The representation of FIG. 11B of hole layer 62 and electron layer 64 is merely illustrative. The boxes in FIG. 11B may represent the HOMO and LUMO for the hole transport layer and electron transport layer, as one example. The hole injection layer and electron injection layer may have similar properties to the hole transport layer and electron transport layer and are therefore not depicted separately in FIG. 11B.

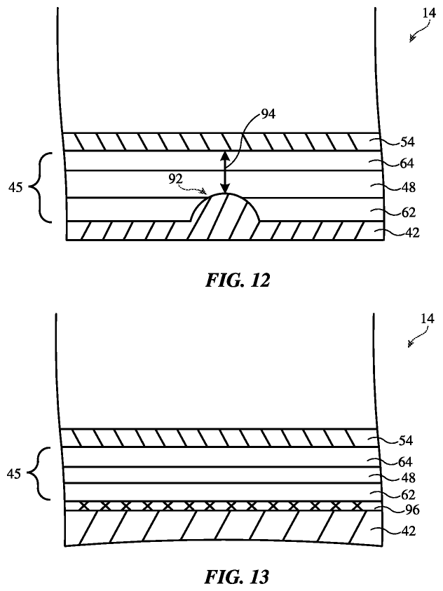

It may be desirable to make anode 42 as smooth as possible to improve performance of the display. FIG. 12 is a cross-sectional side view of an illustrative display showing the effect of anode roughness on the display. As shown, a bump (spike) 92 in the anode causes the anode 42 to contact emissive layer 48 and have a reduced separation distance 94 to cathode 54. This may cause issues in the display. In particular, the anode bump 92 may cause a short circuit between anode 42 and cathode 54, between the anode and the emissive layer 48, and/or between the anode and any other layer in the OLED stack. The bump does not necessarily have to cause the anode to contact the emissive layer 48 (to cause a short circuit). Simply reducing the distance between them may be sufficient to allow shorting behavior. The short circuit(s) prevents the pixel from properly emitting light using OLED layers 45. There are numerous factors that may influence the number of short circuits present within the array of pixels. In general, the surface quality and number of bump-like defects (e.g., surface roughness, crystallinity, grain size, the number of voids, metal oxidation/migration, etc.) of anode 42 may influence the number of short circuits present. Mitigating bumps 92 on anode 42 and improving the surface quality of anode 42 may reduce the number of short circuits and improve display performance.

As one example for mitigating short circuits in the display, the sputtering process used to form anode 42 may be optimized to mitigate surface roughness in the anode. For example, the sputtering power, the sputtering pressure, and/or the sputtering process may be tuned to mitigate surface roughness. Anode 42 may have a Rᵣₘₛ (root mean square roughness) of less than 2 nanometers, less than 1.5 nanometers, less than 1.3 nanometers, less than 1.2 nanometers, less than 1.1 nanometers, less than 1.0 nanometers, between 0.9 and 1.0 nanometers, greater than 0.5 nanometers, between 0.5 nanometers and 1.2 nanometers, etc. For reference, root mean square roughness may refer to the root mean square average of the profile height deviations from the mean line in the anode. Anode 42 may have a Rₚᵥ (peak-to-valley roughness) of less than 14 nanometers, less than 13 nanometers, less than 12 nanometers, between 12 and 13 nanometers, between 12.3 and 12.7 nanometers, etc.

Another technique for mitigating anode surface roughness is shown in FIG. 13. As shown in FIG. 13, the display may include a roughness reduction layer 96 between anode 42 and OLED layers 45. The roughness reduction layer 96 may be formed in direct contact with the upper surface of anode 42. The roughness reduction layer 96 may be formed from a small-molecule material that covers traps in the upper surface of anode 42. One possible material for roughness reduction layer 96 is NDP-9 ((2-(7-dicyanomethylene-1,3,4,5,6,8,9,10-octafluoro-7H-pyrene-2-ylidene)-malononitrile).

Anode surface defects and damaging topology may also be reduced by selecting a smooth anode material. In some cases, the anode may be formed by silver. Other examples for materials used to form anode 42 include tungsten oxide, indium zinc oxide, indium tin oxide, or any other desired material. The anode may also include multiple layers (of one or more materials).

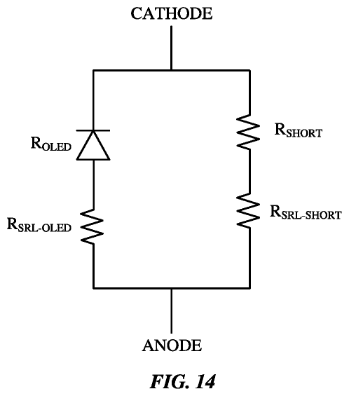

Another technique for mitigating short circuits in the display pixels is to include a high-resistance layer between anode 42 and the OLED layers. This principle is shown in FIG. 14. As shown by the representative circuit diagram in FIG. 14, the organic light-emitting diode (OLED) has a corresponding resistance R_{OLED} between the cathode and the anode. In pixels that have a short circuit between the cathode and the cathode, there is a parallel resistance associated with the short circuit path (R_{SHORT}) between the cathode and the anode.

Ideally, there would not be any short circuits (and therefore no parallel R_{SHORT} resistance). However, anode roughness may cause bumps that provide short circuit paths with a low resistance R_{SHORT}. Some or all of the current may pass through R_{SHORT} instead of R_{OLED} in these instances.

To increase the resistance of the short circuit paths, a thin high-resistance short reduction layer may be added to the pixel. The short reduction layer (SRL) may divert current away from short circuit paths. As shown in FIG. 14, the short reduction layer causes a first resistance R_{SRL-OLED} in the OLED path and a second resistance R_{SRL-SHORT} in the short circuit path. Because the short circuit path has a much smaller area than the OLED path, R_{SRL-SHORT} is much greater than R_{SRL-OLED}. The short reduction layer therefore increases the resistance on the short circuit path by a greater amount than the resistance on the OLED path, ensuring that current leakage on the short circuit path is reduced or eliminated.

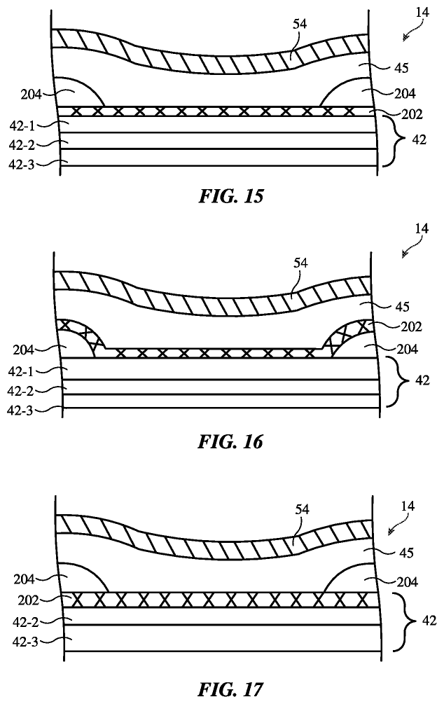

There are various ways for the short reduction layer to be incorporated into the OLED display. FIGS. 15-17 are cross-sectional side views of illustrative OLED displays that include a short reduction layer. The OLED displays of FIGS. 15-17 may include, for example, single anti-node optical cavity pixels of the type shown in FIG. 6.

As shown in FIG. 15, anode 42 may be formed from multiple conductive layers. In the example of FIG. 15, anode 42 includes a first layer 42-1, a second layer 42-2, and a third layer 42-3. The first and third layers 42-1 and 42-3 may be formed from the same material, whereas layer 42-2 may be formed from a different material than layers 42-1 and 42-3. In one example, layers 42-1 and 42-3 may be formed from indium tin oxide (ITO) and layer 42-2 may be formed from silver. This example is merely illustrative. In general, each anode layer may be formed from any desired material (e.g., silver, indium tin oxide, tungsten oxide, indium zinc oxide, etc.).

As shown in FIG. 15, short reduction layer 202 (sometimes referred to as short-circuit-reducing layer 202) may be interposed between anode 42 and OLED layers 45. In one example, short reduction layer 202 may be interposed between and in direct contact with layer 42-1 of anode 42 and the hole injection layer (e.g., HIL 44) of OLED layers 45. The short reduction layer 202 may increase the resistance of short circuit paths between anode 42 and cathode 54, mitigating short circuits in the display.

In the example of FIG. 15, short reduction layer 202 is interposed between anode 42 and pixel definition layer 204. In other words, pixel definition layer 204 is formed over and in direct contact with short reduction layer. Pixel definition layer 204 may define the aperture for each pixel in OLED display 14.

Alternatively, as shown in FIG. 16, short reduction layer 202 may be formed over pixel definition layer 204. Short reduction layer 202 still directly contacts anode 42 within the pixel aperture. However, outside of the pixel aperture the short reduction layer overlaps and directly contacts an upper surface of pixel definition layer 204. The arrangement of FIG. 16 may allow for an easier manufacturing process in some circumstances.

In yet another example, shown in FIG. 17, short reduction layer 202 may take the place of anode layer 42-1 in anode 42. In this arrangement, short reduction layer 202 may be interposed between and in direct contact with anode layer 42-2 (e.g., formed from silver) and OLED layers 45. This type of arrangement may provide the short reduction layer with additional functionality, offering additional performance tuning for the device.

In any of FIGS. 15-17, the thickness of short reduction layer 202 may be less than 100 nanometers, less than 50 nanometers, less than 30 nanometers, less than 10 nanometers, less than 5 nanometers, greater than 1 nanometer, greater than 2 nanometers, greater than 10 nanometers, greater than 25 nanometers, between (inclusive) 2 and 50 nanometers, etc. The short reduction layer may have a sheet resistance of greater than 10⁶ ohms/square, greater than 10⁸ ohms/square, greater than 10⁹ ohms/square, greater than 10¹⁰ ohms/square, greater than 10¹¹ ohms/square, greater than 10¹² ohms/square, less than 10¹⁴ ohms/square, less than 10¹³ ohms/square, between (inclusive) 10⁹ ohms/square and 10¹³ ohms/square, etc. The short reduction layer may be a mix of multiple materials or a pure material. Example materials for the short reduction layer include molybdenum trioxide (MoO₃), vanadium pentoxide (V₂O₅), a tungsten oxide, a mix of indium tin oxide (ITO) and silicon dioxide (SiO₂), a mix of aluminum oxide (Al₂O₃) and zinc oxide (ZnO), tin(IV) oxide (SnO₂), alloys/composites of any two desired materials, etc. These materials are merely illustrative. In general, any desired material(s) may be used to form the short reduction layer 202.

Particles in the OLED stack may also cause electrical shorts between the anode and cathode, reducing in dark pixels. The single anti-node optical cavity pixels may be more sensitive to the presence of particles than dual anti-node optical cavity pixels due to the reduced thickness of the OLED stack. Therefore, OLED displays with single anti-node optical cavity pixels may undergo sub-micron particle screening to screen for small particles (e.g., having a largest dimension less than 1 micron) that may impact the display performance. Additional particle cleaning and scrubbing processes may be used to mitigate the presence of particles in the OLED display.

Using any or all of the aforementioned techniques (e.g., as in FIGS. 13-17) may reduce or eliminate the number of pixels that have a short circuit (and therefore are darker than desired during operation) in the display. As an example, the display (which may include single anti-node cavity OLED pixels with the previously described thicknesses) may have a short circuit in less than 5% of the pixels, less than 1% of the pixels, less than 0.1% of the pixels, less than 0.01% of the pixels, less than 0.001% of the pixels, etc.

Another potential issue with the single anti-node optical cavity pixels described herein is migration of silver from the anode into OLED layers 45. The migration of silver into OLED layers 45 may cause damage to the display such as shorting the anode to the cathode. In particular, consider the example where anode layers 42-1 and 42-3 are formed from indium tin oxide (ITO) and anode layer 42-2 is formed from silver (e.g., a silver alloy). Ideally, anode layers 42-1 and 42-3 will prevent oxidation of the silver in anode layer 42-2, which prevents migration of silver from anode layer 42-2 into OLED layers 45. However, in practice, the thinness of anode layers 42-1 and 42-3 (e.g., less than 200 angstroms thick, less than 150 angstroms thick, less than 100 angstroms thick, etc.) may result in pinholes in anode layers 42-1 and 42-3. Silver in anode layer 42-2 may be oxidized through these pinholes, leading to migration of silver upwards through the pinholes and into OLED layers 45. The example of anode layers 42-1 and 42-3 being formed from indium tin oxide (a transparent conductive oxide) is merely illustrative. In general, anode layers 42-1 and 42-3 may be formed from any desired conductive material.

To mitigate migration of silver through pinholes in anode layer 42-1, the thickness of anode layer 42-1 may be increased to provide a better barrier for oxidation and migration. For example, anode layer 42-1 may have a thickness that is greater than 100 angstroms, greater than 150 angstroms, greater than 200 angstroms, greater than 300 angstroms, etc. The thickness of anode layer 42-1 may be greater than the thickness of anode layer 42-3 by greater than 20 angstroms, greater than 50 angstroms, greater than 100 angstroms, etc.

Alternatively or in addition, the process parameters for forming anode layer 42-1 may be modified to provide a better barrier for oxidation and migration. For example, anode layer 42-1 may be deposited using a sputter process. The sputter process pressure, the sputter process power, and/or the water content in the sputter process may be varied to optimize the barrier properties of anode layer 42-1. Anode layer 42-1 may be divided into multiple discrete depositions to optimize the barrier properties of anode layer 42-1. These process variations may be used to change the density of anode layer 42-1, change the crystallinity of anode layer 42-1, change the morphology of anode layer 42-1, etc. In this way, the pinholes in anode layer 42-1 may be reduced, increasing the barrier to silver migration.

Yet another option to mitigate migration of silver through pinholes in anode layer 42-1 is to modify the process parameters of anode layer 42-2. For example, anode layer 42-2 may be deposited using a sputter process. The sputter process pressure, the sputter process power, and/or the silver alloy content may be varied to reduce the susceptibility of anode layer 42-2 to oxidation and migration.

The material for anode layer 42-1 (and/or anode layer 42-3) may also be changed to provide a better barrier for oxidation and migration of the underlying silver. Anode layer 42-3 may be formed from indium tin oxide whereas anode layer 42-1 is formed from a different material. The different material for anode layer 42-1 may be indium zinc oxide, tungsten oxide, indium gallium zinc oxide, aluminum zinc oxide, aluminum oxide, etc. This example is merely illustrative. Anode layers 42-1 and 42-3 may both be formed from the same material if desired. For example, both anode layers 42-1 and 42-3 may be formed from indium zinc oxide, tungsten oxide, indium gallium zinc oxide, aluminum zinc oxide, aluminum oxide, etc.

Any subset or all of the aforementioned techniques for mitigating migration of silver through pinholes in anode layer may be used in a single display if desired.

The foregoing is merely illustrative and various modifications can be made by those skilled in the art without departing from the scope and spirit of the described embodiments. The foregoing embodiments may be implemented individually or in any combination.

What is claimed is:

1. A display comprising an array of pixels, wherein a pixel in the array of pixels comprises:
an anode;
a cathode, wherein the anode and the cathode define an optical cavity for the pixel; and
organic light-emitting diode layers that are interposed between the anode and the cathode, wherein the organic light-emitting diode layers include an emissive layer, wherein light at a wavelength emitted by the pixel forms a standing wave between the anode and the cathode, wherein the standing wave has only one anti-node, and wherein the emissive layer is aligned with the anti-node of the standing wave.

2. The display defined in claim 1, wherein the pixel further comprises:
a roughness reduction layer that is formed in direct contact with the anode.

3. The display defined in claim 2, wherein the roughness reduction layer is interposed between the anode and the organic light-emitting diode layers.

4. The display defined in claim 1, wherein an upper surface of the anode has a root mean square roughness of less than 1.0 nanometers.

5. The display defined in claim 1, wherein the pixel further comprises:
a short-circuit-reducing layer that is formed between the anode and the organic light-emitting diode layers.

6. The display defined in claim 5, wherein the short-circuit-reducing layer has a sheet resistance between 10⁹ ohms/square and 10¹³ ohms/square.

7. The display defined in claim 5, wherein the short-circuit-reducing layer has a thickness that is between 2 nanometers and 50 nanometers.

8. The display defined in claim 5, wherein the pixel further comprises:
a pixel definition layer, wherein a portion of the short-circuit-reducing layer is interposed between the anode and the pixel definition layer.

9. The display defined in claim 5, wherein the pixel further comprises:
a pixel definition layer, wherein the pixel definition layer is interposed between the anode and a portion of the short-circuit-reducing layer.

10. The display defined in claim 1, wherein the organic light-emitting diode layers further comprise:
a hole injection layer that is interposed between the anode and the emissive layer;
a hole transport layer that is interposed between the hole injection layer and the emissive layer;
an electron blocking layer that is interposed between the hole transport layer and the emissive layer;
an electron injection layer that is interposed between the cathode and the emissive layer;
an electron transport layer that is interposed between the electron injection layer and the emissive layer; and
a hole blocking layer that is interposed between the electron transport layer and the emissive layer.

11. The display defined in claim 10, wherein the hole transport layer has a first highest occupied molecular orbital, wherein the electron blocking layer has a second highest occupied molecular orbital, wherein the emissive layer has a third highest occupied molecular orbital, wherein the hole blocking layer has a fourth highest occupied molecular orbital, wherein the electron transport layer has a fifth highest occupied molecular orbital, wherein the second highest occupied molecular orbital is lower than the first highest occupied molecular orbital, wherein the third highest occupied molecular orbital is lower than the second highest occupied molecular orbital, and wherein the fourth highest occupied molecular orbital is lower than the third and fifth highest occupied molecular orbitals.

12. The display defined in claim 11, wherein the hole transport layer has a first lowest unoccupied molecular orbital, wherein the electron blocking layer has a second lowest unoccupied molecular orbital, wherein the emissive layer has a third lowest unoccupied molecular orbital, wherein the hole blocking layer has a fourth lowest unoccupied molecular orbital, wherein the electron transport layer has a fifth lowest unoccupied molecular orbital, wherein the fourth lowest unoccupied molecular orbital is greater than the fifth lowest unoccupied molecular orbital, wherein the third lowest unoccupied molecular orbital is greater than the fourth lowest unoccupied molecular orbital, and wherein the second lowest unoccupied molecular orbital is greater than the first and third lowest unoccupied molecular orbitals.

13. The display defined in claim 10, wherein the hole transport layer has a hole mobility having a first magnitude and wherein the electron transport layer has an electron mobility having a second magnitude that is within 10% of the first magnitude.

14. The display defined in claim 1, wherein the pixel is a blue pixel, wherein the emissive layer is a blue emissive layer, wherein the blue emissive layer has a spectral output characterized by a wavelength at which intensity is brightest and a full width half maximum, wherein the wavelength is between 445 nanometers and 455 nanometers, and wherein the full width half maximum is between 18 nanometers and 22 nanometers.

15. The display defined in claim 14, wherein the array of pixels further comprises a green pixel having a green emissive layer and a red pixel having a red emissive layer, wherein the green emissive layer has a second spectral output characterized by a second wavelength at which intensity is brightest and a second full width half maximum, wherein the red emissive layer has a third spectral output characterized by a third wavelength at which intensity is brightest and a third full width half maximum, wherein the second wavelength is between 520 nanometers and 530 nanometers, wherein the second full width half maximum is between 26 nanometers and 32 nanometers, wherein the third wavelength is between 620 nanometers and 630 nanometers, and wherein the third full width half maximum is between 30 nanometers and 60 nanometers.

16. A display comprising an array of pixels, wherein a pixel in the array of pixels comprises:
an anode;
a cathode, wherein the anode and the cathode define an optical cavity for the pixel;
organic light-emitting diode layers that are interposed between the anode and the cathode, wherein the organic light-emitting diode layers include an emissive layer, a hole transport layer that is interposed between the emissive layer and the anode, and an electron transport layer that is interposed between the emissive layer and the cathode, wherein light at a wavelength emitted by the pixel forms a standing wave between the anode and the cathode, and wherein the standing wave has only one anti-node; and
a short-circuit-reducing layer that is formed between the anode and the hole transport layer.

17. The display defined in claim 16, wherein the pixel further comprises:
a pixel definition layer that defines an aperture for the pixel.

18. The display defined in claim 17, wherein a portion of the short-circuit-reducing layer is interposed between the anode and the pixel definition layer.

19. The display defined in claim 17, wherein the pixel definition layer is interposed between the anode and a portion of the short-circuit-reducing layer.

20. A display comprising an array of organic light-emitting diode pixels, wherein a pixel in the array of organic light-emitting diode pixels comprises:
an anode;
a cathode, wherein the anode and the cathode define an optical cavity for the pixel;
an emissive layer;
a hole transport layer that is interposed between the emissive layer and the anode;
an electron transport layer that is interposed between the emissive layer and the cathode; and
a roughness reduction layer that is formed in direct contact with the anode, wherein the roughness reduction layer is interposed between the anode and the hole transport layer.
